(19) United States
(12) Patent Application Publication
(10) Pub. No.: US 2005/0073349 A1
(43) Pub. Date: Apr. 7, 2005

(54) Voltage level transferring circuit

(75) Inventor: Ying-Hsin Li, Kaohsiung (TW)

Correspondence Address: LIU & LIU, 811 WEST 7TH STREET, SUITE 1100, LOS ANGELES, CA, 90017, US

(73) Assignee: Toppoly Optoelectronics Corp.

(21) Appl. No.: 10/952,149

(22) Filed: Sep. 27, 2004

(30) Foreign Application Priority Data
Oct. 1, 2003 (TW) 92127148

(51) Int. Cl. H03B 1/00

(52) U.S. Cl. 327/333

(57) ABSTRACT

A voltage level transferring circuit is provided for transferring an input signal oscillating between a high original voltage level and a low original voltage level in a signal input terminal to a target signal oscillating between a high target voltage level and a low target voltage level in a signal output terminal. The circuit includes a voltage pull-up set including a plurality of transistor switches to pull up the voltage from the high original voltage level to the high target voltage level, and a voltage pull-down set including a plurality of transistor switches to pull down the voltage from the low original voltage level to the low target voltage level.

### CROSS-REFERENCE TO RELATED APPLICATION

This application claims the priority benefit of Taiwan application serial no. 92127148, filed on Oct. 1, 2003.

### BACKGROUND OF THE INVENTION

1. Field of the Invention

This invention generally relates to a voltage level transferring circuit, and more particularly to a low energy-consumption voltage level transferring circuit for a liquid crystal display (LCD).

2. Description of Related Art

For the low temperature polysilicon thin film transistor (LTPS TFT) technology, most circuits are formed on the LCD panel. Especially, the vertical driver circuit (or scan driver circuit) is completely formed with LTPS TFTs on the LCD panel. Not only the complexity of the Driving-IC is mitigated, the cost for the Driving-IC is greatly reduced. To reduce the energy consumption, an external voltage, such as, clock signal between 0V˜3.3V, is applied. But the required voltage range for the vertical driver circuit is larger, such as, between ˜5V˜10V. Therefore, the voltage range of the external voltage signal has to be magnified by the voltage level transferring circuit. The voltage level transferring circuit is usually applied to the circuit for raising the writing voltage for the random access memory (RAM) or the read only memory (ROM).

For TFT-LCD, the vertical driver circuit provides the input signal to the gate electrically coupled to each horizontal scan line. The gate of the TFT in the active matrix controls the on/off of the pixel. The voltage level transferring circuit is rarely applied to the LTPS TFT in the active matrix LCD panel. The conventional vertical driver circuit includes a shift register, a voltage level transferring circuit, a buffer and other control circuits. FIG. 1 is schematic diagram of a driver circuit. The external voltage ranges from 0˜5V. However, the voltage applied to the gate of the TFT ranges from −5V˜10V. Hence, the voltage level transferring circuits 123, 126 and 129 are required to magnify the ranges of the input voltage signals between the shift registers 103, 106, and 109 and the scan lines 143, 146, and 149.

FIG. 2 is the first conventional voltage level transferring circuit, which has been disclosed in the U.S. Pat. No. 6,542,144. The voltage level transferring circuit magnifies the voltage range in two steps. The input high voltage level Vdd is first raised to VDD. The input low voltage level Vss is then dropped down to VSS. For example, Vdd is 5V, VDD is 10V, Vss is 0V, and VSS is −5V. Therefore, the input voltage range between 0˜5V is magnified to −5˜10V for the use of the internal LCD panel. Further, this circuit at least requires 8 transistors.

FIG. 3 is the second conventional voltage level transferring circuit, which has been disclosed in the U.S. Pat. No. 6,087,880. This voltage level transferring circuit is suitable for the electrically erasable programmable read only memory (EEPROM). This voltage level transferring circuit requires fewer transistors and can magnify the voltage range in a single step. However, this type of circuit consumes more energy.

### SUMMARY OF THE INVENTION

The present invention is to provide a voltage level transferring circuit for LTPS TFT-LCD in which the operational speed is enhanced, and the number of the transistors and the level of energy consumption are reduced.

In one aspect of the present invention, the present invention provides a voltage level transferring circuit, for transferring an input signal oscillating between a high original voltage level and a low original voltage level in a signal input terminal to a target signal oscillating between a high target voltage level and a low target voltage level in a signal output terminal. The voltage level transferring circuit includes: a first switch having a first terminal, a second terminal and a control terminal, the first terminal of the first switch being electrically coupled to the high target voltage level, the control terminal of the first switch being electrically coupled to the signal output terminal; a second switch having a first terminal, a second terminal, a third terminal and a control terminal, the first terminal of the second switch being electrically coupled to the second terminal of the first switch, the control terminal of the second switch being electrically coupled to the signal input terminal, the second terminal of the second switch being electrically coupled to the low original voltage level; a third switch having a first terminal, a second terminal, a third terminal and a control terminal, the first terminal of the third switch being electrically coupled to the high original voltage level, the control terminal of the third switch being electrically coupled to the signal input terminal; a fourth switch having a first terminal, a second terminal and a control terminal, the first terminal of the fourth switch being electrically coupled to the second terminal of the third switch, the second terminal of the fourth switch being electrically coupled to the low target voltage level, the control terminal of the fourth switch being electrically coupled to the signal output terminal; a fifth switch having a first terminal, a second terminal and a control terminal, the first terminal of the fifth switch being electrically coupled to the high target voltage level, the second terminal of the fifth switch being electrically coupled to the signal output terminal, the control terminal of the fifth switch being electrically coupled to the third terminal of the second switch; and a sixth switch having a first terminal, a second terminal and a control terminal, the first terminal of the sixth switch being electrically coupled to the signal output terminal, the second terminal of the sixth switch being electrically coupled to the low target voltage level, the control terminal of the sixth switch being electrically coupled to the third terminal of the third switch.

In a preferred embodiment, when the input signal is at the high original voltage level, the first and sixth switches are off, the first terminal and the third terminal of the second switch are disconnected, the second terminal and the third terminal of the second switch are connected, the first terminal and the third terminal of the third switch are disconnected, the second terminal and the third terminal of the third switch are connected, and the fourth and fifth switches are on; when the input signal is at the low original voltage level, the fourth and fifth switches are off, the first terminal and the third terminal of the second switch are connected, the second terminal and the third terminal of the second switch are disconnected, the first terminal and the third terminal of the third switch are connected, the second terminal and the third terminal of the third switch are disconnected, and the first and sixth switches are on.

In another aspect of the present invention, the present invention provides a voltage level transferring circuit, for transferring an input signal oscillating between a high original voltage level and a low original voltage level in a signal input terminal and an inverse signal input terminal to a target signal oscillating between a high target voltage level and a low target voltage level in a signal output terminal. The voltage level transferring circuit comprises: a first switch having a first terminal, a second terminal, and a control terminal, the first terminal of the first switch being electrically coupled to the high target voltage level; a second switch having a first terminal, a second terminal, and a control terminal, the first terminal of the second switch being electrically coupled to the second terminal of the first switch, the control terminal of the second switch being electrically coupled to the signal input terminal; a third switch having a first terminal, a second terminal, and a control terminal, the first terminal of the third switch being electrically coupled to the second terminal of the second switch, the control terminal of the third switch being electrically coupled to the signal input terminal, the second terminal of the third switch being electrically coupled to the low original voltage level; a fourth switch having a first terminal, a second terminal, and a control terminal, the first terminal of the fourth switch being electrically coupled to the high target voltage level, the control terminal of the fourth switch being electrically coupled to the second terminal of the second switch; a fifth switch having a first terminal, a second terminal, and a control terminal, the first terminal of the fifth switch being electrically coupled to the second terminal of the fourth switch, the control terminal of the fifth switch being electrically coupled to the inverse signal input terminal; a sixth switch having a first terminal, a second terminal, and a control terminal, the first terminal of the sixth switch being electrically coupled to the control terminal of the first switch and to the second terminal of the fifth switch, the control terminal of the sixth switch being electrically coupled to the inverse signal input terminal, the second terminal of the sixth switch being electrically coupled to the low original voltage level; a seventh switch having a first terminal, a second terminal, and a control terminal, the first terminal of the seventh switch being electrically coupled to the high original voltage level, the control terminal of the seventh switch being electrically coupled to the signal input terminal; an eighth switch having a first terminal, a second terminal, and a control terminal, the first terminal of the eighth switch being electrically coupled to the second terminal of the seventh switch, the control terminal being electrically coupled to the signal input terminal; a ninth switch having a first terminal, a second terminal, and a control terminal, the first terminal of the ninth switch being electrically coupled to the second terminal of the eighth switch, the second terminal of the ninth switch being electrically coupled to the low target voltage level; a tenth switch having a first terminal, a second terminal, and a control terminal, the first terminal of the tenth switch being electrically coupled to the high original voltage level, the control terminal of the tenth switch being electrically coupled to the inverse signal input terminal; an eleventh switch having a first terminal, a second terminal, and a control terminal, the first terminal of the eleventh switch being electrically coupled to the second terminal of the tenth switch and to the control terminal of the ninth switch, the control terminal of the eleventh switch being electrically coupled to the inverse signal input terminal; a twelfth switch having a first terminal, a second terminal, and a control terminal, the first terminal of the twelfth switch being electrically coupled to the second terminal of the eleventh switch, the control terminal of the twelfth switch being electrically coupled to the second terminal of the seventh switch, the second terminal of the twelfth switch being electrically coupled to the low target voltage level; a thirteenth switch having a first terminal, a second terminal, and a control terminal, the first terminal of the thirteenth switch being electrically coupled to the high target voltage level, the control terminal of the thirteenth switch being electrically coupled to the first terminal of the sixth switch, the second terminal of the thirteen switch being electrically coupled to the signal output terminal; a fourteenth switch having a first terminal, a second terminal, and a control terminal, the first terminal of the fourteenth switch being electrically coupled to the signal output terminal, the control terminal of the fourteen switch being electrically coupled to the first terminal of the eleventh switch, the second terminal of the fourteenth switch being electrically coupled to the low target voltage level; and an inverter having an input terminal and an output terminal, the input terminal of the inverter being electrically coupled to the signal input terminal, the output terminal of the inverter being electrically coupled to the inverse signal input terminal.

In a preferred embodiment, when the input signal is at the high original voltage level, the first, second, sixth, seventh, eleventh, twelfth, and thirteenth switches are off, and the third, fourth, fifth, eighth, ninth, tenth, and fourteenth switches are on; when the input signal is at the low original voltage level, the third, fourth, fifth, eighth, ninth, tenth, and fourteenth switches are off, and the first, second, sixth, seventh, eleventh, twelfth, and thirteenth switches are on.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIG. 1 is a schematic diagram of a driver circuit according to prior art.

FIG. 2 is a schematic diagram of the first conventional voltage level transferring circuit.

FIG. 3 is a schematic diagram of the second conventional voltage level transferring circuit.

FIG. 4 is a schematic diagram of a voltage level transferring circuit in accordance with the first preferred embodiment of the present invention.

FIG. 5 is a schematic diagram of a voltage level transferring circuit in accordance with the second preferred embodiment of the present invention.

FIG. 6A is a schematic diagram showing a comparison of the voltage waveforms between the first conventional voltage level transferring circuit and the voltage level transferring circuit of the first preferred embodiment of the present invention.

FIG. 6B is a schematic diagram showing a comparison of the output currents between the first conventional voltage level transferring circuit the voltage level transferring circuit of the first preferred embodiment of the present invention.

FIG. 7A is a schematic diagram showing a comparison of the output currents in high voltage level between the second conventional voltage level transferring circuit and the voltage level transferring circuit of the first preferred embodiment of the present invention.

FIG. 7B is a schematic diagram showing a comparison of the output currents in low voltage level between the second conventional voltage level transferring circuit and the voltage level transferring circuit of the first preferred embodiment of the present invention.

FIG. 8, is an electronic device employs a data driver containing a level transferring circuit according to an embodiment of the present invention.

### DESCRIPTION OF THE PREFERRED EMBODIMENTS

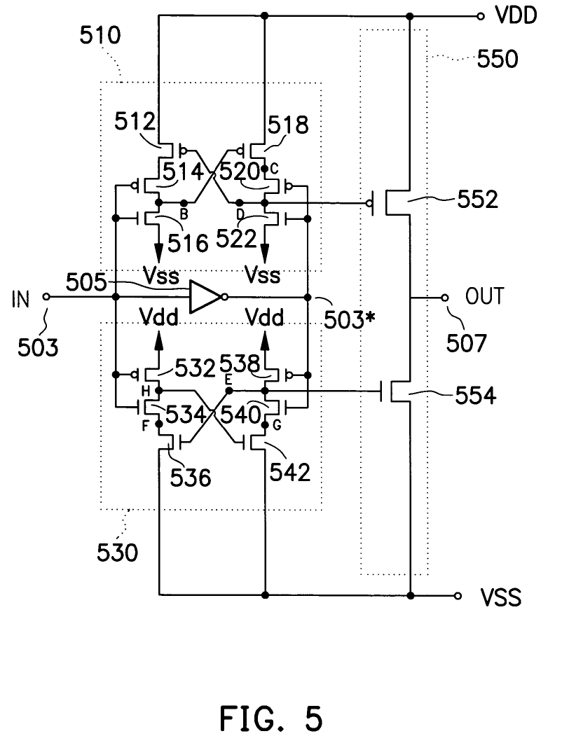

FIG. 4 is schematic diagram of a voltage level transferring circuit # in accordance with one embodiment of the present invention. The voltage level transferring circuit includes a signal input terminal 403, a signal output terminal 407, a voltage pull-up set 410, and a voltage pull-down set 420. The signal input terminal 403 receives an input signal oscillating between a high original voltage level/signal Vdd and a low original voltage level/signal Vss. The signal output terminal 407 outputs a target signal oscillating between a high target voltage level/signal VDD and a low target voltage level/signal VSS. The high target voltage level VDD is higher than the high original voltage level Vdd. The low target voltage level VSS is lower than the low original voltage level Vss. Although in this embodiment, an inverter 405 is electrically coupled to the signal input terminal 403, the present invention is limited to these of the signal input terminal of the inverter as the signal input terminal as in this embodiment.

The voltage pull-up set 410 includes a fifth switch 418, a first switch 412 and a second switch 419. The voltage pull-up set 410 is electrically coupled to the signal input terminal 403, the high target voltage level VDD and the low original voltage level Vss, for receiving the input signal and pull up the high original voltage level Vdd to the high target voltage level VDD. The fifth switch 418 having a first terminal, a second terminal, and a control terminal, wherein the first terminal of the fifth switch is electrically coupled to the high target voltage level VDD. The control terminal of the fifth switch is electrically coupled to the second switch 419. The second terminal of the fifth switch is electrically coupled to the signal output terminal 407 and connects the high target voltage level VDD and the signal output terminal 407 based on the voltage level of the control terminal. In this embodiment, the fifth switch 418 can be a P-type transistor 417. The first switch 412 is electrically coupled to and between the high target voltage level VDD and the second switch 419. The first switch 412 can also be a P-type transistor 413. The second switch 419 is electrically coupled to the signal input terminal 403, the fifth switch 418, and the first switch 412. The second switch 419 is comprised with a P-type transistor 414 and an N-type transistor 416 series-connected together. The N-type transistor 416 is electrically coupled to the low original voltage level Vss, while the P-type transistor 414 is electrically coupled to the first switch 412.

The voltage pull-down set 420 includes the sixth switch 428, the fourth switch 426 and the third switch 429. The voltage pull-down set 420 is electrically coupled to the signal input terminal 403, the high original voltage level Vdd, and the low target voltage level VSS for receiving the input signal and pulling down the low original voltage level Vss to the low target voltage level VSS. The sixth switch 428 has a first terminal, a second terminal, and a control terminal. The first terminal of the sixth switch is electrically coupled to the signal output terminal 407. The control terminal of the sixth switch is electrically coupled to the third switch 429 and connects the low target voltage level VSS and the signal output terminal 407. In this embodiment, the sixth switch 428 can be an N-type transistor 427. The fourth switch 426 is electrically coupled to and between the low target voltage level VSS and the third switch 429. The fourth switch 426 can also be an N-type transistor 425. The third switch 429 is electrically coupled to the signal input terminal 403, the sixth switch 428 and the fourth switch 426. The third switch 429 is comprised with a P-type transistor 422 and an N-type transistor 424 series-connected together. The P-type transistor 422 is electrically coupled to the high original voltage level Vdd, while the N-type transistor 424 is electrically coupled to the fourth switch 426.

When the input signal is higher than Vdd, the potential at point A is Vss because the inverter 405 inverts the input signal and the P-type transistor 422 of the third switch 429 is turned on. The potential at point C is Vdd. Because the gate voltage level Vdd of the N-type transistor 427 is much larger than the source voltage VSS, the N-type transistor 427 is turned on. Then, the signal output terminal 407 outputs a low target voltage level VSS. To check if the circuit is stable, the target voltage VSS is sent to the P-type transistor 413 to turn on the P-type transistor 413. Hence, the potential at point D is VDD. Because the gate voltage level Vss of the P-type transistor 414 is much smaller than the source voltage VDD, the P-type transistor 414 is turned on, and the potential at point B is VDD. Hence, the gate voltage of the N-type transistor 416 is Vss and turned off. Further, the gate voltage of the P-type transistor 417 is VDD and the P-type transistor 417 is turned off. Hence, the entire circuit is stable.

When the input signal is smaller than Vss, the potential at point A is Vdd because the inverter 405 inverts the input signal, and the N-type transistor 416 is turned on. The potential at point B is Vss. Because the gate voltage level Vss of the P-type transistor 417 is much smaller than the source voltage VDD, the P-type transistor 417 is turned on. Then, the signal output terminal 407 outputs a high target voltage level VDD. To check if the circuit is stable, the target voltage VDD is sent to the N-type transistor 425 to turn on the N-type transistor 425. Hence, the potential at point E is VSS. Because the gate voltage level Vdd of the N-type transistor 424 is much higher than the source voltage VSS, the N-type transistor 424 is turned on, and the potential at point C is VSS. The gate voltage of the P-type transistor 422 is Vdd and the P-type transistor 422 is turned off, while the gate voltage of the N-type transistor 427 is VSS and the N-type transistor 427 is turned off. Consequently, the entire circuit is stable.

Therefore, when the input signal is at the high original voltage level Vdd, the target signal outputted by the signal output terminal 407 is the low target voltage level VSS. When the input signal is at the low original voltage level Vss, the target signal outputted by the signal output terminal 407 is the high target voltage level VDD. In other words, the output signal has the opposite phase to the input signal. If the signal input terminal is not electrically coupled to the inverter 405, the output signal has the same phase as the input signal.

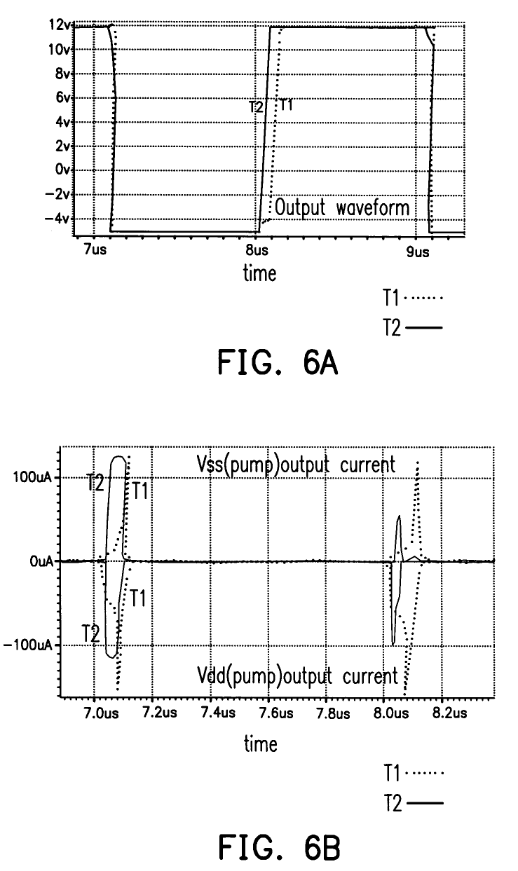

FIG. 5 is a voltage level transferring circuit in accordance with the another embodiment of the present invention. The voltage level transferring circuit includes a signal input terminal 503, a signal output terminal 507, a voltage pull-up set 510, and a voltage pull-down set 530. In this embodiment, the P-type transistor 552 of the thirteenth switch and the N-type transistor 554 of the fourteen switch 554 are comprised of an output switch 550. The voltage pull-up set 510 includes a P-type transistor 512 of the first switch, a P-type transistor 514 of the second switch, an N-type transistor 516 of the third switch, a P-type transistor 518 of the fourth switch, a P-type transistor 520 of the fifth switch, and an N-type transistor 522 of the sixth switch. The voltage pull-down set 530 includes a P-type transistor 532 of the seventh switch, an N-type transistor 534 of the eighth switch, an N-type transistor 536 of the ninth switch, a P-type transistor 538 of the tenth switch, an N-type transistor 540 of the eleventh switch, and an N-type transistor 542 of the twelfth switch. The circuit further includes an inverter 505 between the signal input terminal 503 and the inverse signal input terminal 503′. The circuit includes the voltage pull-up set 510, the voltage pull-down set 530, and the output switch 550. The voltage pull-up set 510 pulls up the high original voltage level Vdd to the high target voltage level VDD. The voltage pull-down 510 pulls down the low original voltage level Vss to the low target voltage level VSS. Then, the output voltage levels VDD and VSS are used to control the P-type transistor 552 and the N-type transistor 554 of the output switch. By controlling the on/off of the P-type transistor 552 and the N-type transistor 554, the target signal becomes a signal oscillating between a high target voltage level VDD and a low target voltage level VSS.

When the input signal is higher than Vdd, the inverse signal input terminal 503* is Vss because the inverter 505 inverts the input signal; the N-type transistor 516 of the voltage pull-up set 510 is turned on, but the N-type transistor 522 is turned off. The potential at point B is Vss, which turns on the P-type transistor 518, and the potential at point C is VDD. The P-type transistor 520 is turned on, and the potential at point D is VDD. Then, VDD is sent to the P-type transistor 512 to turn off the P-type transistor 512. Consequently, no current passes through the P-type transistors 512 and 514, and the N-type transistor 516. Hence, the output voltage level of the voltage pull-up set 510 is the target high voltage level VDD.

When the input signal is lower than Vss, the inverse signal input terminal 503* is Vdd because the inverter 505 inverts the input signal; the N-type transistor 534 and P-type transistor 538 of the voltage pull-up set 530 are turned on, but the P-type transistor 532 is turned off. The potential at point E is Vdd, which turns on the N-type transistor 536, and the potential at point F is VSS. The N-type transistor 534 is turned on, and the potential at point H is VSS. Then, VSS is sent to the N-type transistor 542 to turn off the N-type transistor 542. Consequently, no current passes through the N-type transistors 540 and 542, and the P-type transistor 538. Because the voltage of the point D turns off the P-type transistor 552, and the voltage of the point E turns on the N-type transistor 554, the output voltage level of the voltage pull-down set 530 is the target low voltage level VSS.

The voltage pull-up set 510 pulls up the high original voltage level Vdd to the high target voltage level VDD. The voltage pull-down 510 pulls down the low original voltage level Vss to the low target voltage level VSS. Because the P-type transistor 552 is controlled by the point D, and the N-type transistor 554 is controlled by the by the point E, and the potentials at the points D and E are opposite under the same condition. In other words, when the P-type transistor 552 is on/off, the N-type transistor 554 is off/on.

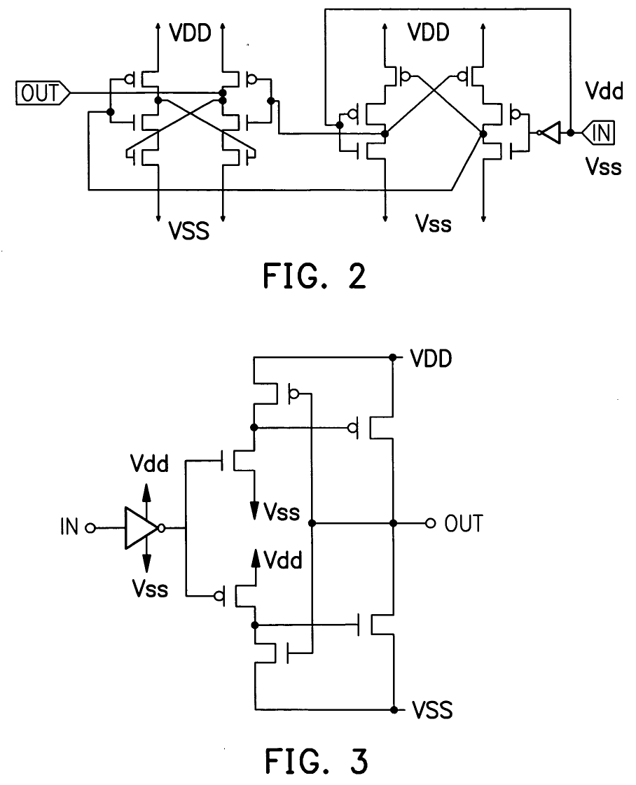

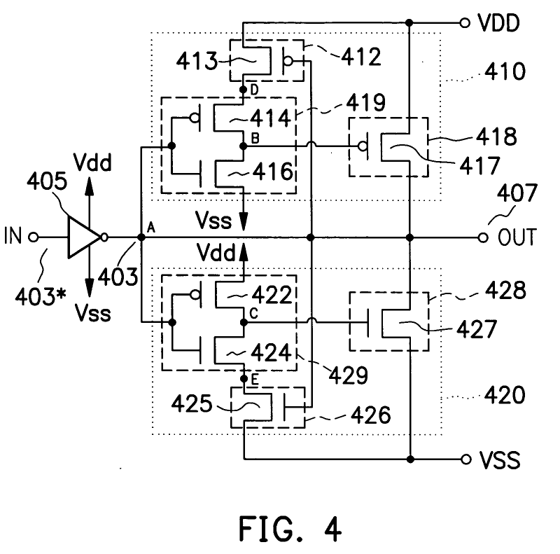

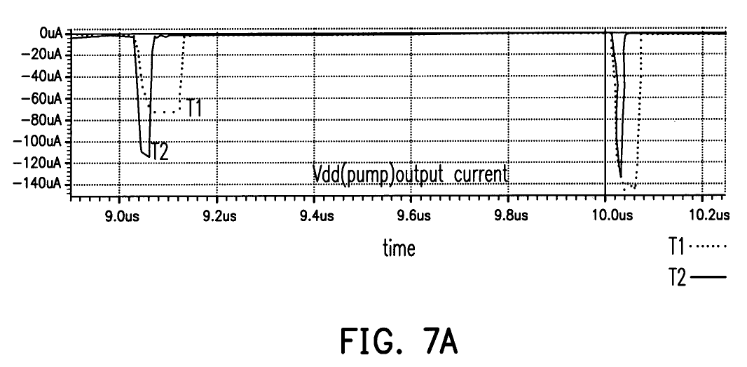

FIG. 6A is a schematic diagram showing a comparison of the voltage waveform between the first conventional voltage level transferring circuit and the voltage level transferring circuit of the first preferred embodiment of the present invention. FIG. 6B is a schematic diagram showing a comparison of the output currents between the first conventional voltage level transferring circuit the voltage level transferring circuit of the first preferred embodiment of the present invention. Referring to FIG. 6A, T1 represents the output voltage waveform of the conventional circuit and T2 represents the output voltage waveform of the voltage level transferring circuit of the first preferred embodiment. As shown in FIG. 6A, the first preferred embodiment has a faster response speed than the conventional circuit. Referring to FIG. 6B, T1 represents the output current waveform of the conventional circuit and T2 represents the output current waveform of the voltage level transferring circuit of the first preferred embodiment. Because the power consumption is equal to the product of the voltage and the current, the area enclosed by the current is proportional to the power consumption. As shown in FIG. 6B, the areas of T1 and T2 are almost the same. Further, referring to FIGS. 2 and 4, the number of the transistors in the first embodiment is fewer than that of the first conventional circuit.

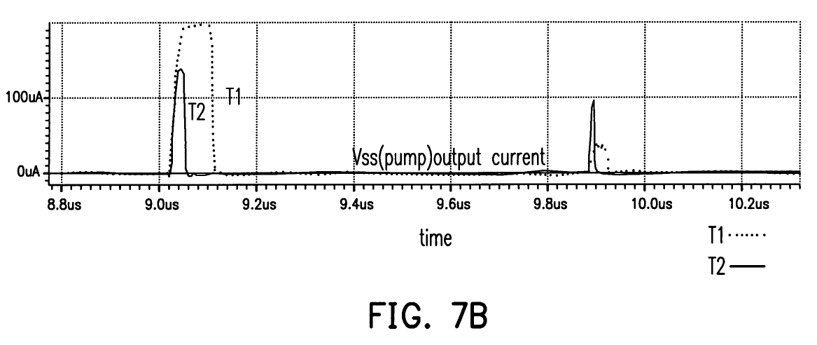

Referring to FIG. 7A, T1 represents the output current of the second conventional circuit and T2 represents the output current of the voltage level transferring circuit of the first preferred embodiment. As shown in FIGS. 7A and 7B, the area enclosed by the current in the first embodiment is much smaller than the second conventional circuit.

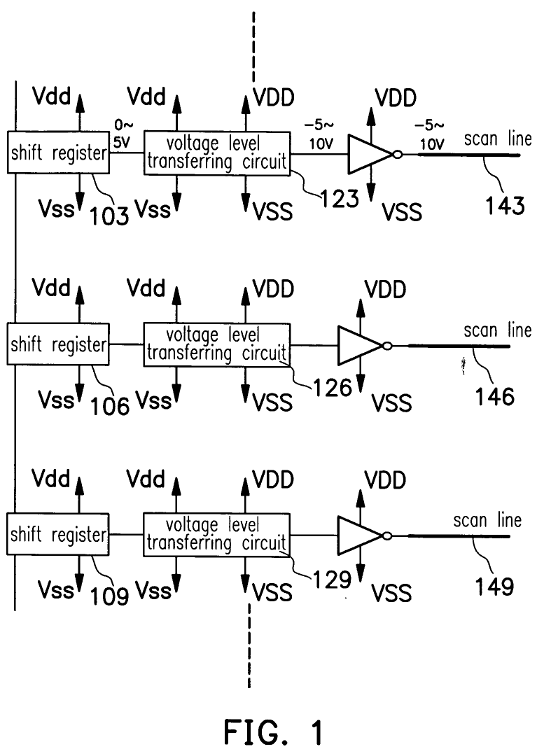

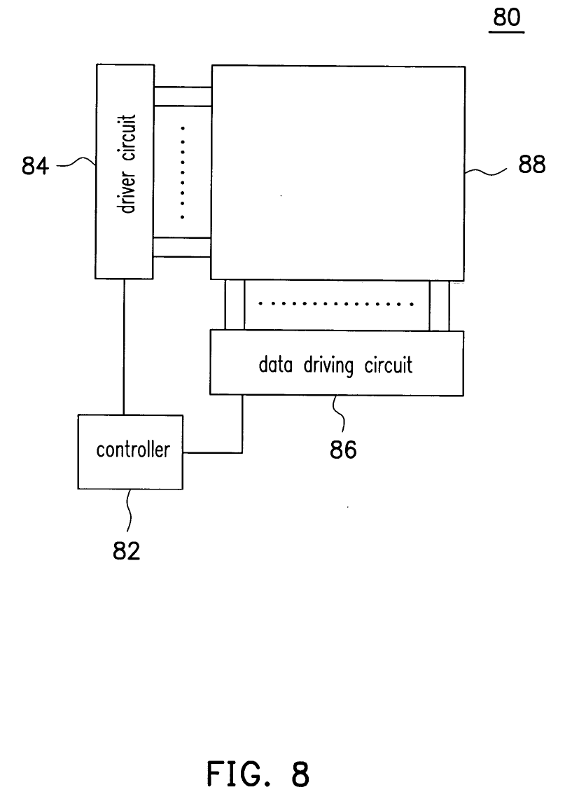

For further implementation, the voltage level transferring circuit could be used as element 123, 126 or 129 in a driver circuit as shown in FIG. 1. Moreover, referring to FIG. 8, an electronic device employs a driver circuit containing a level transferring circuit according to an embodiment of the present application is provided. In the embodiment, the electronic device contains a controller 82, a driver circuit 84, a data driving circuit 86 and a liquid crystal display element 88. The controller 82 operatively coupled to the driver circuit 84 and the data driving circuit 86 for controlling the operation of the liquid crystal display element 88 to display an image in accordance with image data. As can be seen from the drawing, the structure of the electronic device 80 is the same as a normal LCD display device since the voltage level transferring circuit could be perfectly combined into the prior art circuit.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

1. A voltage level transferring circuit, comprising:
a signal input terminal, for receiving an input signal having high and low input signals,
a signal output terminal, for outputting a target signal having high and low target signals;
a first switch electrically coupled to said high target signal and to said signal output terminal;
a second switch electrically coupled to said first switch, and to said signal input terminal, and to said low input signal;
a third switch electrically coupled to said high input signal and to said signal input terminal;
a fourth switch electrically coupled to said third switch, to said low target signal, and to said signal output terminal;
a fifth switch electrically coupled to said high target signal, to said signal output terminal, and to said second switch; and
a sixth switch electrically coupled to said signal output terminal, to said low target signal, and to said third switch.

2. The voltage level transferring circuit of claim 1, wherein at least one of the first, second, third, fourth, fifth and sixth switches include low temperature polysilicon thin film transistors (LTPS TFT).

3. The voltage level transferring circuit of claim 1, wherein when said input signal is at said high original voltage level, said first and sixth switches are off, said first terminal and said third terminal of said second switch are disconnected, said second terminal and said third terminal of said second switch are connected, said first terminal and said third terminal of said third switch are disconnected, said second terminal and said third terminal of said third switch are connected, and said fourth and fifth switches are on; when said input signal is at said low original voltage level, said fourth and fifth switches are off, said first terminal and said third terminal of said second switch are connected, said second terminal and said third terminal of said second switch are disconnected, said first terminal and said third terminal of said third switch are connected, said second terminal and said third terminal of said third switch are disconnected, and said first and sixth switches are on.

4. The voltage level transferring circuit of claim 1, further comprising an inverter electrically coupled to said signal input terminal.

5. The voltage level transferring circuit of claim 1, wherein said first and fifth switches are P-type transistors.

6. The voltage level transferring circuit of claim 1, wherein said fourth and sixth switches are N-type transistors.

7. The voltage level transferring circuit of claim 1, wherein each of said second and third switches includes a N-type transistor and a P-type transistor connected in series.

8. A voltage level transferring circuit, for transferring an input signal oscillating between a high original voltage level and a low original voltage level in a signal input terminal and an inverse signal input terminal to a target signal oscillating between a high target voltage level and a low target voltage level in a signal output terminal, said voltage level transferring circuit comprising:
a first switch comprising a first terminal, a second terminal, and a control terminal, said first terminal of said first switch being electrically coupled to said high target voltage level;
a second switch comprising a first terminal, a second terminal, and a control terminal, said first terminal of said second switch being electrically coupled to said second terminal of said first switch, said control terminal of said second switch being electrically coupled to said signal input terminal;
a third switch comprising a first terminal, a second terminal, and a control terminal, said first terminal of said third switch being electrically coupled to said second terminal of said second switch, said control terminal of said third switch being electrically coupled to said signal input terminal, said second terminal of said third switch being electrically coupled to said low original voltage level;
a fourth switch comprising a first terminal, a second terminal, and a control terminal, said first terminal of said fourth switch being electrically coupled to said high target voltage level, said control terminal of said fourth switch being electrically coupled to said second terminal of said second switch;
a fifth switch comprising a first terminal, a second terminal, and a control terminal, said first terminal of said fifth switch being electrically coupled to said second terminal of said fourth switch, said control terminal of said fifth switch being electrically coupled to said inverse signal input terminal;
a sixth switch comprising a first terminal, a second terminal, and a control terminal, said first terminal of said sixth switch being electrically coupled to said control terminal of said first switch and to said second terminal of said fifth switch, said control terminal of said sixth switch being electrically coupled to said inverse signal input terminal, said second terminal of said sixth switch being electrically coupled to said low original voltage level;
a seventh switch comprising a first terminal, a second terminal, and a control terminal, said first terminal of said seventh switch being electrically coupled to said high original voltage level, said control terminal of said seventh switch being electrically coupled to said signal input terminal;
an eighth switch comprising a first terminal, a second terminal, and a control terminal, said first terminal of said eighth switch being electrically coupled to said second terminal of said seventh switch, said control terminal being electrically coupled to said signal input terminal;
a ninth switch comprising a first terminal, a second terminal, and a control terminal, said first terminal of said ninth switch being electrically coupled to said second terminal of said eighth switch, said second terminal of said ninth switch being electrically coupled to said low target voltage level;
a tenth switch comprising a first terminal, a second terminal, and a control terminal, said first terminal of said tenth switch being electrically coupled to said high original voltage level, said control terminal of said tenth switch being electrically coupled to said inverse signal input terminal;
an eleventh switch comprising a first terminal, a second terminal, and a control terminal, said first terminal of said eleventh switch being electrically coupled to said second terminal of said tenth switch and to said control terminal of said ninth switch, said control terminal of said eleventh switch being electrically coupled to said inverse signal input terminal;
a twelfth switch comprising a first terminal, a second terminal, and a control terminal, said first terminal of said twelfth switch being electrically coupled to said second terminal of said eleventh switch, said control terminal of said twelfth switch being electrically coupled to said second terminal of said seventh switch, said second terminal of said twelfth switch being electrically coupled to said low target voltage level;
a thirteenth switch comprising a first terminal, a second terminal, and a control terminal, said first terminal of said thirteenth switch being electrically coupled to said high target voltage level, said control terminal of said thirteenth switch being electrically coupled to said first terminal of said sixth switch, said second terminal of said thirteen switch being electrically coupled to said signal output terminal;
a fourteenth switch comprising a first terminal, a second terminal, and a control terminal, said first terminal of said fourteenth switch being electrically coupled to said signal output terminal, said control terminal of said fourteen switch being electrically coupled to said first terminal of said eleventh switch, said second terminal of said fourteenth switch being electrically coupled to said low target voltage level; and
an inverter comprising an input terminal and an output terminal, said input terminal of said inverter being electrically coupled to said signal input terminal, said output terminal of said inverter being electrically coupled to said inverse signal input terminal.

9. The voltage level transferring circuit of claim 8, wherein when said input signal is at said high original voltage level, said first, second, sixth, seventh, eleventh, twelfth, and thirteenth switches are off, and said third, fourth, fifth, eighth, ninth, tenth, and fourteenth switches are on; when said input signal is at said low original voltage level, said third, fourth, fifth, eighth, ninth, tenth, and fourteenth switches are off, said first, second, sixth, seventh, eleventh, twelfth, and thirteenth switches are on.

10. The voltage level transferring circuit of claim 8, wherein said first, second, fourth, fifth, seventh, tenth, and thirteenth switches are P-type transistors.

11. The voltage level transferring circuit of claim 8, wherein said third, sixth, eighth, ninth, eleventh, twelfth, and fourteenth switches are N-type transistors.

12. A driver circuit for a liquid crystal display, comprising:
a shift register, receiving a signal for driving a display element;
a voltage level transferring circuit of claim 1, coupled to the shift register for receiving the signal outputted from the shift register and amplifies the signal to a working voltage; and
a buffer, coupled to the voltage level transferring circuit for receiving the working voltage and outputting the working voltage to drive the display element.

13. An electronic device, comprising:
a liquid crystal display element;
a driver circuit as in claim 12, operatively coupled to the liquid crystal display element; and
a controller operatively coupled to the driver circuit for controlling the operation of the liquid crystal display element to display an image.
